(19) United States
(12) Patent Application Publication
(10) Pub. No.: US 2024/0322524 A1
(43) Pub. Date: Sep. 26, 2024

(54) PHOTONIC CRYSTAL ELECTRICALLY PUMPED SURFACE-EMITTING LASER AND PREPARATION METHOD THEREOF

(71) Applicant: The Chinese University of Hong Kong, Shenzhen, Shenzhen (CN)

(72) Inventors: Zhaoyu Zhang, Shenzhen (CN); Ping Sun, Shenzhen (CN); Wentao Xie, Shenzhen (CN); Yuanhao Gong, Shenzhen (CN); Xiaolei Shen, Shenzhen (CN)

(21) Appl. No.: 18/530,244

(22) Filed: Dec. 6, 2023

(30) Foreign Application Priority Data
Mar. 23, 2023 (CN) 202310286370.5

(51) Int. Cl. H01S 5/183; H01S 5/042; H01S 5/343

(52) U.S. Cl. CPC H01S 5/183; H01S 5/04254; H01S 5/04256; H01S 5/343

(57) ABSTRACT

A photonic crystal electrically pumped surface-emitting laser includes: a lower electrode; a substrate stacked above the lower electrode; a first conductive semiconductor layer stacked above the substrate; an active emitting layer stacked above the first conductive semiconductor layer; a second conductive semiconductor layer stacked above the active emitting layer, wherein the second conductive semiconductor layer includes a photonic crystal formed in alternating regions of different refractive indices, and arranged in a photonic bandgap within the second conductive semiconductor layer; and an upper electrode stacked above the second conductive semiconductor layer.

### CROSS REFERENCE TO RELATED APPLICATIONS

The present application claims the benefit of Chinese Patent Application No. 202310286370.5 filed on Mar. 23, 2023, the contents of which are incorporated herein by reference in their entirety.

### TECHNICAL FIELD

At least one embodiment of the present disclosure relates to the field of semiconductor lasers, and particularly to a photonic crystal electrically pumped surface-emitting laser and a preparation method thereof.

### BACKGROUND

Semiconductor lasers have been widely used in applications such as optical communication, optical storage, displays, and even 3D sensing due to their small size, high reliability, and low cost. In the past decade, various types of semiconductor lasers have been developed, including edge-emitting lasers, vertical cavity surface-emitting lasers (VCSELs), and distributed feedback lasers. Among them, surface-emitting lasers can be integrated (arrayed) on the same substrate to emit coherent light in parallel, making them promising as excellent light sources for inter-chip, intra-chip, inter-board, intra-board, and intra-network optical transmission. They can also serve as excellent light sources for nanophotonic circuits, optoelectronic integrated circuits, and optoelectronic hybrid integrated circuits. However, traditional surface-emitting lasers are limited by their own structure, resulting in large vertical divergence angles and poor beam quality, requiring complex beam shaping techniques.

Photonic crystals, by mimicking the periodic structure of crystals, artificially construct photonic bandgaps to regulate the states of photons. Therefore, introducing photonic crystal structures into surface-emitting lasers can efficiently utilize light and significantly reduce their vertical divergence angles. Currently, photonic crystal surface-emitting lasers are mainly divided into band-gap type (also called defect type), and band-edge type. Defect-type photonic crystal lasers confine electromagnetic waves to form high-quality, low-threshold lasers, but it is difficult to achieve high power. On the other hand, band-edge photonic crystals can generate slow light to prolong the lifetime of photons inside the photonic crystal and enhance the interaction between photons and the gain medium. These lasers do not confine the resonant region to a small volume but extend it throughout the photonic crystal, enabling large-area coherent oscillation. Subsequently, the laser is diffracted out from the surface-of the photonic crystal to achieve surface-emission. Therefore, photonic crystal surface-emitting lasers (PCSELs) with large emission areas, narrow divergence angles, high power output, and ease of fabricating 2D laser arrays have gained widespread attention and application. It is worth noting that in practical applications, achieving high-power lasers through electrical injection is still limited by current distribution and the photonic crystal itself.

Currently, the processing methods for electrically pumped photonic crystal surface-emitting lasers mainly include wafer bonding, secondary epitaxy, and direct etching of the photonic crystal structure from top to bottom. The first two techniques were proposed by Noda from Kyoto University in 1999 and 2014, respectively, and lasers with high power and good beam quality were fabricated. Nevertheless, wafer bonding and secondary epitaxy remain complex processing techniques, and direct etching of the photonic crystal structure from top to bottom can form localized energy levels at the periodic structure of the photonic crystal, leading to non-radiative recombination and threshold reduction. Therefore, there is an urgent need for a simple processing method for electrically pumped photonic crystal surface-emitting lasers that can achieve uniform current injection, reduce leakage, and decrease non-radiative recombination.

### SUMMARY

According to embodiments of the disclosure, a photonic crystal electrically pumped surface-emitting laser and methods for preparing the laser are provided to solve at least one technical problem in the prior art.

According to a first aspect, a photonic crystal electrically pumped surface-emitting laser includes: a lower electrode; a substrate stacked above the lower electrode; a first conductive semiconductor layer stacked above the substrate; an active emitting layer stacked above the first conductive semiconductor layer; a second conductive semiconductor layer stacked above the active emitting layer, wherein the second conductive semiconductor layer includes a photonic crystal formed in alternating regions of different refractive indices, and arranged in a photonic bandgap within the second conductive semiconductor layer; and an upper electrode stacked above the second conductive semiconductor layer, wherein the upper electrode includes a transparent conductive nanomaterial layer, a transparent conductive material layer, and a metal conductive layer stacked in sequence, and wherein the lower edge of the transparent conductive nanomaterial layer is connected to the second conductive semiconductor layer, and the upper edge of the transparent conductive nanomaterial layer is connected to the transparent conductive material layer.

With reference to the first aspect, in an embodiment, the transparent conductive nanomaterial layer includes two-dimensional graphene nanosheets, two-dimensional molybdenum disulfide nanosheets, two-dimensional hexagonal boron nitride nanosheets, and one-dimensional silver nanowires; the transparent conductive material layer is made of indium tin oxide material, and the preparation method of the transparent conductive material layer is magnetron sputtering; and the upper electrode conductive material of the metal conductive layer is Ag, and the lower electrode conductive material of the metal conductive layer is AuGeNi or Ti or Au.

With reference to the first aspect, in an embodiment, the second conductive semiconductor layer allows for a photonic crystal resonance to the light emitted from the active emitting layer, and the metal conductive layer reflects the light of the photonic crystal resonance to the lower electrode.

With reference to the first aspect, in an embodiment, the active emitting layer has a quantum well structure repeated 1-5 times.

With reference to the first aspect, in an embodiment, the active emitting layer includes sequentially stacked layers, including a quantum lower barrier layer, a quantum well layer and a quantum upper barrier layer.

With reference to the first aspect, in an embodiment, the material of the quantum well structure of the active emitting layer is selected from a group consisting of: indium phosphide arsenide, gallium nitride, indium gallium arsenide phosphide, indium gallium nitride, indium gallium phosphide, aluminum gallium arsenide indium, aluminum gallium indium phosphide, indium phosphide arsenide phosphide, and combination thereof.

With reference to the first aspect, in an embodiment, the quantum well structure of the active emitting layer includes quantum dots of which the material is selected from a group consisting of: indium phosphide arsenide, gallium nitride, indium gallium arsenide phosphide, indium gallium nitride, indium gallium phosphide, aluminum gallium arsenide indium, aluminum gallium indium phosphide, and indium phosphide arsenide phosphide, and combination thereof.

With reference to the first aspect, in an embodiment, the first conductive semiconductor layer includes a lower contact layer stacked on the substrate, a lower cladding layer stacked on the lower contact layer, and a lower waveguide layer stacked on the lower cladding layer.

With reference to the first aspect, in an embodiment, the first conductive semiconductor layer is made of one or more materials selected from AlGalnP, InP, or AlₓGa₍₁₋ₓ₎As, where 0<x≤1.

With reference to the first aspect, in an embodiment, the first conductive semiconductor layer is doped with carbon, and the carbon doping concentration in the lower contact layer is higher than that in the lower cladding layer; and the carbon doping concentration in the lower cladding layer is higher than that in the lower waveguide layer.

With reference to the first aspect, in an embodiment, the laser further includes a first gradient layer arranged between the lower contact layer and the substrate, wherein the material composition of the first gradient layer gradually changes from that of the substrate material to the lower contact layer.

With reference to the first aspect, in an embodiment, the second conductive semiconductor layer includes an upper waveguide layer stacked on the active emitting layer, an upper cladding layer stacked on the upper waveguide layer, and an upper contact layer stacked on the upper cladding layer, and wherein the upper contact layer includes a first upper contact layer and a second upper contact layer stacked on top of the first upper contact layer.

With reference to the first aspect, in an embodiment, the second conductive semiconductor layer is made of one or more materials selected from AlGalnP, InP, or AlₓGa₍₁₋ₓ₎As, where 0≤ x≤1.

With reference to the first aspect, in an embodiment, the second conductive semiconductor layer is doped with silicon, the upper contact layer is made of GaAs material, and the silicon doping concentration in the first upper contact layer is higher than that in the second upper contact layer.

With reference to the first aspect, in an embodiment, the laser further includes a second gradient layer arranged between the upper cladding layer and the upper contact layer, wherein the material composition of the second gradient layer gradually changes from the upper contact layer to the upper cladding layer.

With reference to the first aspect, in an embodiment, the upper cladding layer includes a first upper cladding layer, a second upper cladding layer, and a third upper cladding layer, in a sequential arrangement; and the silicon doping concentrations in the first upper cladding layer, the second upper cladding layer and the third upper cladding layer gradually decrease.

According to a second aspect, a method for preparing the photonic crystal electrically pumped surface-emitting laser includes: preparing a solution of graphene oxide dilute or MXene; applying the prepared solution onto the second conductive semiconductor layer having a photonic crystal structure, to obtain a transparent conductive nanomaterial; stacking transparent conductive materials and metal conductive materials sequentially on the transparent conductive nanomaterial; and depositing a lower metal electrode beneath the substrate.

With reference to the second aspect, in an embodiment, the method further includes: preparing the solution of graphene oxide dilute by an improved Hummer's method; applying the solution of graphene oxide dilute onto the second conductive semiconductor layer and carrying out a Langmuir-Blodgett film self-assembly method to obtain a large-area graphene two-dimensional nanosheet; and reducing graphene oxide in the large-area graphene two-dimensional nanosheet by hydroiodic acid to obtain the transparent conductive nanomaterial.

According to a third aspect, a method for preparing the photonic crystal electrically pumped surface-emitting laser includes: preparing a silver nanowire solution; applying the silver nanowire solution onto a second conductive semiconductor layer having a photonic crystal structure, to obtain a transparent conductive nanomaterial; stacking transparent conductive materials and metal conductive materials on the transparent conductive nanomaterial sequentially; and depositing a lower metal electrode beneath the substrate.

According to a fourth aspect, a method for preparing the photonic crystal electrically pumped surface-emitting laser includes: preparing a large-area transparent conductive two-dimensional graphene oxide nanosheet on a nickel substrate by a metal organic vapor deposition method; transferring the graphene oxide nanosheet onto the second conductive semiconductor layer having a photonic crystal structure; stacking transparent conductive materials and metal conductive materials successively; and depositing lower metal electrode beneath the substrate.

With respect to the photonic crystal electrically pumped surface-emitting laser and the preparation method in the above embodiments of the disclosure, the introduction of a photonic crystal structure in the surface-emitting laser with contact to conductive nanomaterial allows for efficient utilization of light and significant reduction in the vertical divergence angle of the light, so as to enable uniform current injection, reducing leakage and minimizing non-radiative recombination.

### DESCRIPTION OF DRAWINGS

Certain embodiments of the present disclosure are illustrated, by way of example, in the figures of the accompanying drawings, in which like references indicate similar elements.

FIG. 1 shows a structure of the photonic crystal electrically pumped surface-emitting laser according to the disclosure.

FIG. 2 shows a cross-sectional shape of different refractive index regions in the photonic crystal electrically pumped surface-emitting laser according to the disclosure.

FIG. 3 shows a first preparation method of the photonic crystal electrically pumped surface-emitting laser according to the disclosure.

FIG. 4 shows a second preparation method of the photonic crystal electrically pumped surface-emitting laser according to the disclosure.

FIG. 5 shows a third preparation method of the photonic crystal electrically pumped surface-emitting laser according to the disclosure.

FIG. 6 shows a fourth preparation method of the photonic crystal electrically pumped surface-emitting laser according to the disclosure.

FIG. 7 is an electron micrograph of the photonic crystal electrically pumped surface-emitting laser with contact conductive nanomaterial according to the disclosure.

### DETAILED DESCRIPTION

The following will provide a clear and complete description of the concept, specific structure, and technical effects of the disclosure, with the help of embodiments and accompanying drawings, in order to fully understand the purpose, solution, and effects of the disclosure. It should be noted that, unless conflicting, the features in the embodiments of this application can be combined with each other.

Furthermore, unless otherwise specified, when a feature is referred to as “fixed” or “connected” to another feature, it can be directly or indirectly fixed or connected to the other feature. Additionally, the terms “up,” “down,” “left,” “right,” “top,” “bottom,” and similar descriptions used in this disclosure are relative to the positional relationship between the components of the disclosure as depicted in the drawings.

Moreover, unless otherwise defined, all technical and scientific terms used in this document have the same meaning as commonly understood by those skilled in the art. The terms used in this document are only for describing specific embodiments and should not be construed as limiting the disclosure. The term “and/or” used herein includes any combination of one or more of the listed items.

It should be understood that, although the terms “first,” “second,” “third,” etc., may be used to describe various components in this disclosure, these components should not be limited to these terms. These terms are used to distinguish components of the same type from each other. For example, without departing from the scope of this disclosure, the first component may also be referred to as the second component, and similarly, the second component may also be referred to as the first component.

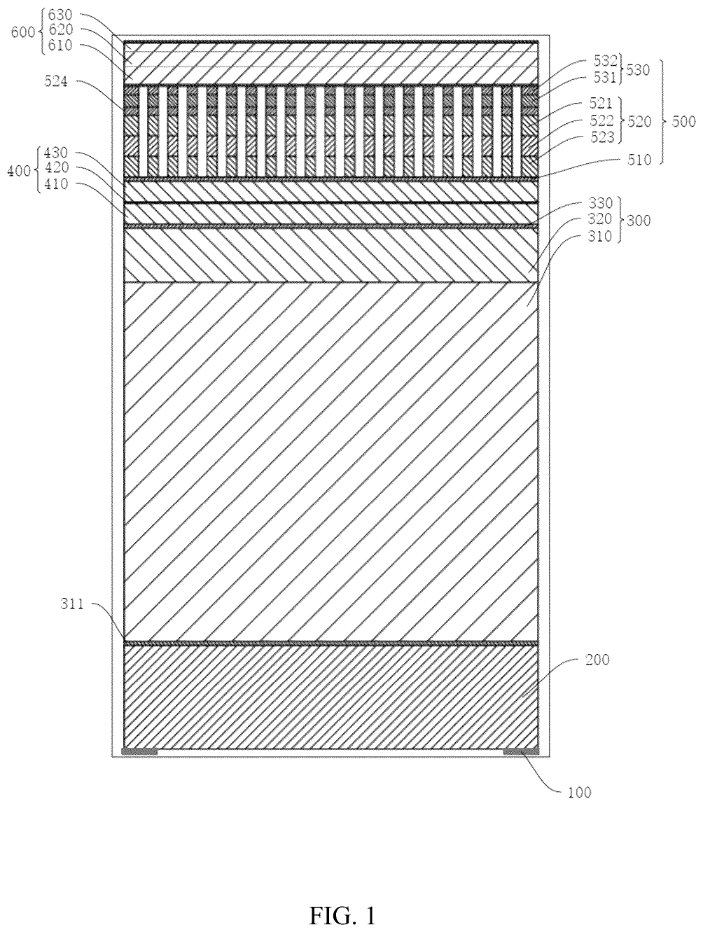

Referring to FIG. 1, in some embodiments, a photonic crystal pump surface-emitting laser according to the disclosure includes: a lower electrode 100; a substrate 200 stacked above the lower electrode 100; a first conductive semiconductor layer 300 stacked above the substrate 200; an active emitting layer 400 stacked above the first conductive semiconductor layer 300; a second conductive semiconductor layer 500 stacked above the active emitting layer 400; and an upper electrode 600, which is stacked above the second conductive semiconductor layer 500.

The second conductive semiconductor layer 500 includes a photonic crystal formed in alternating regions of different refractive indices, wherein the photonic crystal is arranged in the second conductive semiconductor layer 500 after forming a photonic bandgap therein.

The upper electrode 600 includes a transparent conductive nanomaterial layer 610, a transparent conductive material layer 620, and a metal conductive layer 630, which are successively stacked from bottom to top, wherein the lower edge of the transparent conductive nanomaterial layer 610 is connected to the second conductive semiconductor layer 500, and the upper edge of the transparent conductive nanomaterial layer 610 is connected to the transparent conductive material layer 620.

It should be mentioned that the second conductive semiconductor layer 500 is stacked directly or via an intermediate layer on a semiconductor substrate, and the second conductive semiconductor layer 500 consists of semiconductor materials such as GaAs, InP, GaP, GaNAs, etc.

It should be mentioned that methods for forming the semiconductor layer stack include metal organic chemical vapor deposition (MOCVD), metal organic molecular beam epitaxy (MOMBE), chemical beam epitaxy (CBE), etc.

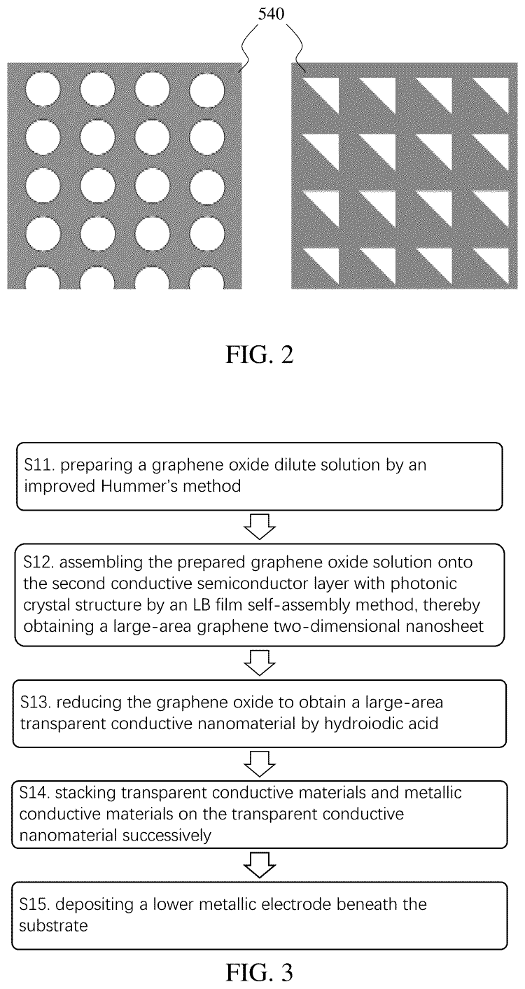

Referring to FIG. 2, in some embodiments, different refractive index regions are formed within the second conductive semiconductor layer to create a two-dimensional photonic crystal structure 540 having holes. It should be furtherly mentioned that, in order to confine light better, the bottoms of the holes can reach the upper waveguide layer 510. In a diffractive photonic crystal laser, the relationship between the photonic band structure of the photonic crystal structure and the gain of the active layer is set to the Brillouin zone Γ point (in-plane wave vector is 0) or the frequency of the edge light is consistent with the frequency of the gain of the active layer. Furthermore, the relationship between the lattice arrangement of the photonic crystal and the gain of the active layer is set to a wide photonic bandgap, and the energy levels are set to be located in the gap, with the frequency of the energy levels being consistent with the frequency of the gain of the active layer.

It should be mentioned that, in an example, low refractive index air holes are formed by dry etching or wet etching methods to constitute a photonic crystal. Preferably, dry etching is ideal due to the higher vertical velocity compared to the horizontal velocity. Preferably, dry etching utilizes high-density plasma sources such as Inductively Coupled Plasma (ICP) etching and Electron Cyclotron Resonance (ECR) etching to further improve the anisotropic etching.

Additionally, it should be mentioned that different refractive index regions can also be achieved by injecting other materials or modifying the materials.

Referring to FIG. 2, in some embodiments, the cross-sectional shape in the different refractive index regions can be arranged in various closed shapes such as circular, rectangular, elliptical, and various polygons. The formed photonic band modes include edge modes and gap modes.

Referring to FIG. 1, in some embodiments, the transparent conductive nanomaterial layer 610 includes two-dimensional graphene nanosheets, two-dimensional MXene nanosheets, two-dimensional hexagonal boron nitride (h-BN) nanosheets, and one-dimensional silver nanowires. The transparent conductive material layer 620 is made of indium tin oxide (ITO) material, and the preparation method of the transparent conductive material layer 620 is magnetron sputtering, which is used to reduce the optical loss factor and balance carrier injection. The upper electrode conductive material of the metal conductive layer 630 is Ag, and the lower electrode conductive material of the metal conductive layer 630 is AuGeNi or Ti or Au. The light emitted from the light-emitting active layer 400 is reflected back to the opposite direction of the laser after the photonic crystal resonance in the second conductive semiconductor layer 500, and then emitted through the lower electrode 100.

Referring to FIG. 7, where the transparent conductive nanomaterial layer prevents transparent conductive materials or metal materials from entering the photonic crystal structure. This layer reduces damage, minimizes leakage current, balances carrier injection, and decreases contact resistance. The transparent conductive material is indium tin oxide (ITO), prepared through magnetron sputtering, to reduce the optical loss factor and balance carrier injection. The light emitted by the active emitting layer 400 passes through photonic crystal resonance and is reflected in the opposite direction by the conductive material, then exits through the light-emitting port of the lower electrode 100.

Referring to FIG. 1, in some embodiments, the active emitting layer 400 is a quantum well structure consisting of successively stacked quantum lower barrier layer 410, quantum well layer 420, and quantum upper barrier layer 430 from bottom to top. The quantum well structure of the active emitting layer 400 is repeated 1-5 times.

Referring to FIG. 1, in some embodiments, the quantum well structure of the luminescent active layer 400 is made of one or more materials, including indium phosphide arsenide (InAsP), gallium nitride (GaN), indium gallium arsenide (InGaAs), indium gallium nitride (InGaN), indium gallium phosphide (InGaP), aluminum gallium indium arsenide (AlGaInAs), aluminum gallium indium phosphide (AlGalnP), and gallium indium arsenide phosphide (GaInAsP).

Additionally, the quantum well structure of the luminescent active layer 400 also includes quantum dots, which are made of one or more materials, including indium phosphide arsenide (InAsP), gallium nitride (GaN), indium gallium arsenide (InGaAs), indium gallium nitride (InGaN), indium gallium phosphide (InGaP), aluminum gallium indium arsenide (AlGaInAs), aluminum gallium indium phosphide (AlGalnP), and gallium indium arsenide phosphide (GaInAsP).

Referring to FIG. 1, in some embodiments, the first conductive semiconductor layer 300 includes the lower contact layer 310 stacked on the substrate 200, the lower cladding layer 320 stacked on the lower contact layer 310, and the lower waveguide layer 330 stacked on the lower cladding layer 320. The first conductive semiconductor layer 300 is made of one or more materials, including AlGalnP, InP, or AlₓGa₍₁₋ₓ₎As, where 0<x≤1. The first conductive semiconductor layer 300 is doped with carbon, with the carbon doping concentration in the lower contact layer 310 being higher than that in the lower cladding layer 320, and the carbon doping concentration in the lower cladding layer 320 being higher than that in the lower waveguide layer 330. The lower contact layer 310 and the substrate 200 also include a first grading layer 311, wherein the material composition of first grading layer 311 gradually changes from that of substrate material to the lower contact layer 310. The first grading layer 311 herein is used to prevent lattice mismatch.

Referring to FIG. 1, in some embodiments, the upper cladding layer 520 includes, a first upper cladding layer 521, a second upper cladding layer 522, and a third upper cladding layer 523 from top to bottom. The silicon doping concentration in the first upper cladding layer 521, the second upper cladding layer 522, and the third upper cladding layer 523 gradually decreases.

The disclosure also provides methods for preparing a photonic crystal electrically pumped surface-emitting laser in contact with conductive nanomaterial. The methods are described in the following embodiments.

### Embodiment I

Referring to FIG. 3, a method for preparing a photonic crystal electrically pumped surface-emitting laser includes the following steps of:
S11. preparing a dilute graphite oxide solution with a certain concentration by an improved Hummer's method;
S12. applying (or assembling) the prepared graphite oxide solution onto the second conductive semiconductor layer etching a photonic crystal structure by a Langmuir-Blodgett film (LB film) self-assembly method, so as to obtain a large-area graphene two-dimensional nanosheet;
S13. reducing the graphite oxide in the graphene nanosheet by hydroiodic acid, so as to obtain a large-area transparent conductive nanomaterial contact layer;
S14. stacking transparent conductive materials and metal conductive materials on the transparent conductive nanomaterial contact layer successively; and
S15. depositing a lower metal electrode beneath the substrate.

Regarding the step S11, in an example, the improved Hummer's method is implemented by the following experiment steps. Assemble a reaction bottle of 500 ml in an ice-water bath, mix 5 g of graphite powder and 5 g of sodium nitrate with 200 ml of concentrated sulfuric acid, add 25 g of potassium chlorate evenly, then add 15 g of potassium permanganate in multiple portions while controlling the temperature below 20° C. After stirring for a period of time, remove the ice bath and continue stirring for 24 hours. Slowly add 200 ml of deionized water, raise the temperature to 98° C., stir for 20 minutes, then add hydrogen peroxide, centrifuge, wash, and vacuum dry to obtain a dilute graphite oxide powder. Finally, add a certain amount of water to adjust the concentration to 0.1-1 mg/mL.

### Embodiment II

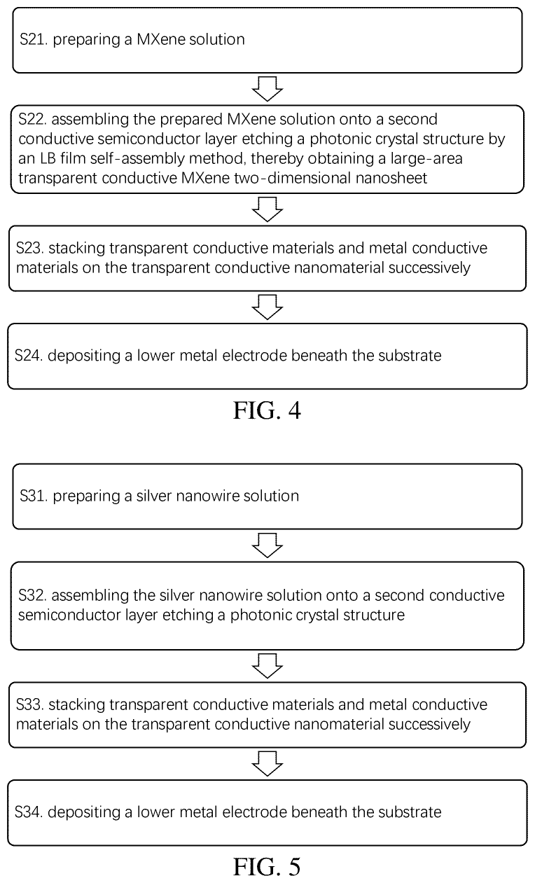

Refer to FIG. 4, a method for preparing a photonic crystal electrically pumped surface-emitting laser includes the following steps of:
S21. preparing a dilute MXene solution with a certain concentration;
S22. applying (or assembling) the prepared MXene solution onto the second conductive semiconductor layer etching a photonic crystal structure by the Langmuir-Blodgett film (LB film) self-assembly method, so as to obtain a large-area transparent conductive MXene two-dimensional nanosheet;
S23. stacking transparent conductive materials and metal conductive materials on the transparent conductive nanomaterial contact layer (of the MXene two-dimensional nanosheet) successively; and
S24. depositing a lower metal electrode beneath the substrate.

Regarding the step S21, in an example, the preparation of MXene solution of a certain concentration is implemented by the following experiment steps. By the minimally intensive layer delamination (MILD) method, add 20 mL of HCl solution (9M) and 1.0 g of lithium fluoride (LiF) to a 100 mL Teflon container, stir at room temperature to obtain a uniform solution. Then, add 1.0 g of Ti₃AlC₂ powder to the above solution. After etching at 38° C. for 48 hours, centrifuge the suspension at a speed of 3500 rpm for 15 minutes, then wash the precipitate with deionized water until the pH reaches 7.0. Disperse the precipitate in deionized water and perform ultrasonication. After centrifugation at 10,000 rpm for 10 minutes, separate the supernatant, and freeze-dry to obtain MXene powder. Finally, add a certain amount of water to adjust the concentration to 0.1 mg/mL-1 mg/mL.

### Embodiment III

Referring to FIG. 5, a method for preparing a photonic crystal electrically pumped surface-emitting laser includes the following steps of:
S31. preparing a silver nanowire solution with a certain concentration;
S32. applying (or assembling) the silver nanowire solution onto the second conductive semiconductor layer etching a photonic crystal structure;
S33. stacking transparent conductive materials and metal conductive materials on the transparent conductive nanomaterial contact layer successively; and
S34. depositing a lower metallic electrode beneath the substrate.

Regarding the step S31, in an example, the preparation of the silver nanowire solution with a certain concentration is implemented by the following experiment steps. Synthesize silver nanowires by a common hard template method, reduce silver nitrate solution with acetaldehyde to allow the silver nanowires to grow in the pores of anodic aluminum oxide (AAO) thin template, and react for 3 hours to obtain dense nanowires. Finally, add a certain amount of water to adjust the concentration to 0.1 mg/mL-1 mg/mL.

### Embodiment IV

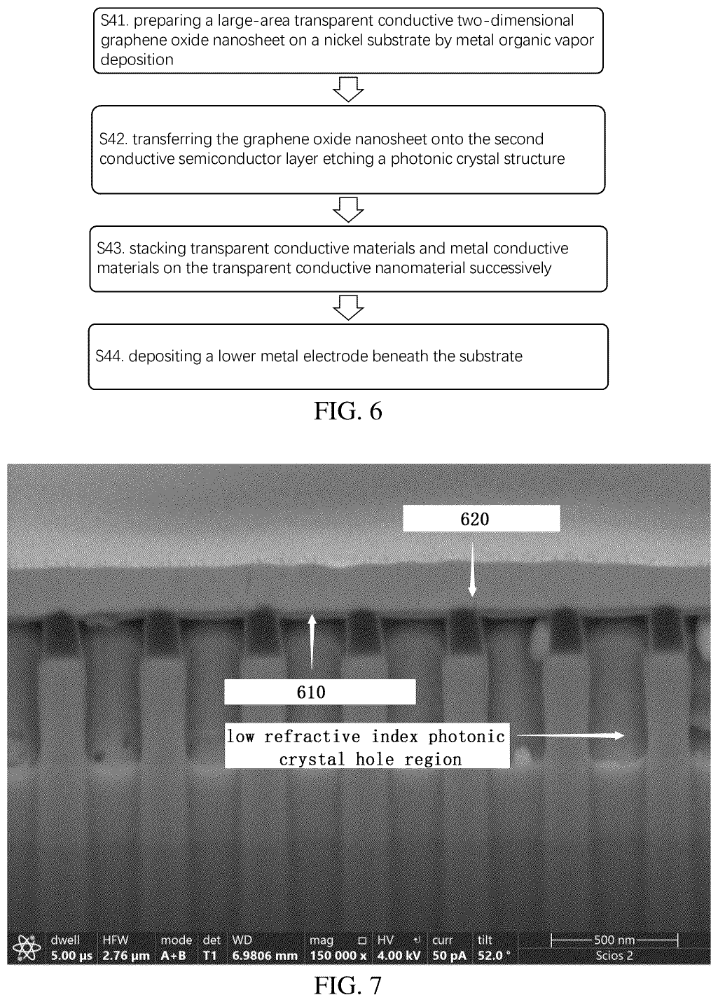

Referring to FIG. 6, a method for preparing a photonic crystal electrically pumped surface-emitting laser includes the following steps of:
S41. preparing a large-area transparent conductive two-dimensional graphene nanosheet on a nickel substrate by a metal organic chemical vapor deposition (MOCVD) method;
S42. transferring the graphene nanosheets onto the second conductive semiconductor layer with the photonic crystal structure;
S43. stacking transparent conductive materials and metal conductive materials on the transparent conductive nanomaterial contact layer successively; and
S44. depositing a lower metal electrode below the substrate.

Regarding the step S41, in an example, the preparation of the two-dimensional graphene nanosheet is implemented by the following experiment. First, the substrate metal foil is placed in a furnace, hydrogen and argon or nitrogen gas are introduced for protection, and heated to about 1000° C., maintaining a stable temperature for about 20 minutes. Then, the protective gas flow is stopped, and a carbon source gas (such as methane) is introduced for about 30 minutes to complete the reaction. The power supply is cut off, methane gas is closed, and the protective gas is introduced to purge the methane gas. The tube is cooled to room temperature in the protective gas environment, and the metal foil is taken out to obtain large-area graphene nanosheets on the metal foil.

The above description is only a preferred embodiment of the disclosure. The disclosure is not limited to the above embodiments. As long as the same means can achieve the technical effects of the disclosure, any modifications, equivalent substitutions, improvements, etc., made within the spirit and principles disclosed herein should be included within the scope of the disclosure. Various modifications and variations can be made to the technical solution and/or implementation method within the scope of the disclosure.

### LIST OF REFERENCE SIGNS

100 bottom electrode
200 substrate
300 first conductive semiconductor layer
310 lower contact layer
311 first gradient layer
320 lower cladding layer
330 lower waveguide layer
400 active emitting layer
410 quantum lower barrier layer
420 quantum well layer
430 quantum upper barrier layer
500 second conductive semiconductor layer
510 upper waveguide layer
520 upper cladding layer
521 first upper cladding layer
522 second upper cladding layer
523 third upper cladding layer
524 second gradient layer
530 upper contact layer
531 first upper contact layer
532 second upper contact layer
540 two-dimensional photonic crystal structure
600 upper electrode
610 transparent conductive nanomaterial layer
620 transparent conductive material layer
630 metal conductive layer

1. A photonic crystal electrically pumped surface-emitting laser, comprising:
a lower electrode;
a substrate stacked above the lower electrode;
a first conductive semiconductor layer stacked above the substrate;
an active emitting layer stacked above the first conductive semiconductor layer;
a second conductive semiconductor layer stacked above the active emitting layer, wherein the second conductive semiconductor layer comprises a photonic crystal formed in alternating regions of different refractive indices, and arranged in a photonic bandgap within the second conductive semiconductor layer; and
an upper electrode stacked above the second conductive semiconductor layer, wherein the upper electrode comprises a transparent conductive nanomaterial layer, a transparent conductive material layer, and a metal conductive layer stacked in sequence, and wherein the lower edge of the transparent conductive nanomaterial layer is connected to the second conductive semiconductor layer, and the upper edge of the transparent conductive nanomaterial layer is connected to the transparent conductive material layer.

2. The laser of claim 1, wherein:
the transparent conductive nanomaterial layer comprises two-dimensional graphene nanosheets, two-dimensional molybdenum disulfide nanosheets, two-dimensional hexagonal boron nitride nanosheets, and one-dimensional silver nanowires;
the transparent conductive material layer is made of indium tin oxide material, and the preparation method of the transparent conductive material layer is magnetron sputtering; and
the upper electrode conductive material of the metal conductive layer is Ag, and the lower electrode conductive material of the metal conductive layer is AuGeNi or Ti or Au.

3. The laser of claim 2, wherein
the second conductive semiconductor layer allows for a photonic crystal resonance to the light emitted from the active emitting layer, and
the metal conductive layer reflects the light of the photonic crystal resonance to the lower electrode.

4. The laser of claim 1, wherein
the active emitting layer has a quantum well structure repeated 1-5 times.

5. The laser of claim 4, wherein
the active emitting layer comprises sequentially stacked layers, including a quantum lower barrier layer, a quantum well layer and a quantum upper barrier layer.

6. The laser of claim 4, wherein
the material of the quantum well structure of the active emitting layer is selected from a group consisting of: indium phosphide arsenide, gallium nitride, indium gallium arsenide phosphide, indium gallium nitride, indium gallium phosphide, aluminum gallium arsenide indium, aluminum gallium indium phosphide, indium phosphide arsenide phosphide, and combination thereof.

7. The laser of claim 4, wherein
the quantum well structure of the active emitting layer comprises quantum dots of which the material is selected from a group consisting of: indium phosphide arsenide, gallium nitride, indium gallium arsenide phosphide, indium gallium nitride, indium gallium phosphide, aluminum gallium arsenide indium, aluminum gallium indium phosphide, and indium phosphide arsenide phosphide, and combination thereof.

8. The laser of claim 1, wherein
the first conductive semiconductor layer comprises a lower contact layer stacked on the substrate, a lower cladding layer stacked on the lower contact layer, and a lower waveguide layer stacked on the lower cladding layer.

9. The laser of claim 8, wherein
the first conductive semiconductor layer is made of one or more materials selected from AlGaInP, InP, or AlₓGa₍₁₋ₓ₎As, where 0<x≤1.

10. The laser of claim 9, wherein:
the first conductive semiconductor layer is doped with carbon, and the carbon doping concentration in the lower contact layer is higher than that in the lower cladding layer; and
the carbon doping concentration in the lower cladding layer is higher than that in the lower waveguide layer.

11. The laser of claim 8, comprising
a first gradient layer arranged between the lower contact layer and the substrate, wherein the material composition of the first gradient layer gradually changes from that of the substrate material to the lower contact layer.

12. The laser of claim 1, wherein
the second conductive semiconductor layer comprises an upper waveguide layer stacked on the active emitting layer, an upper cladding layer stacked on the upper waveguide layer, and an upper contact layer stacked on the upper cladding layer, and wherein the upper contact layer comprises a first upper contact layer and a second upper contact layer stacked on top of the first upper contact layer.

13. The laser of claim 12, wherein
the second conductive semiconductor layer is made of one or more materials selected from AlGaInP, InP, or AlₓGa₍₁₋ₓ₎As, where 0≤ x≤1.

14. The laser of claim 13, wherein
the second conductive semiconductor layer is doped with silicon, the upper contact layer is made of GaAs material, and the silicon doping concentration in the first upper contact layer is higher than that in the second upper contact layer.

15. The laser of claim 12, comprising
a second gradient layer arranged between the upper cladding layer and the upper contact layer, wherein the material composition of the second gradient layer gradually changes from the upper contact layer to the upper cladding layer.

16. The laser of claim 12, wherein:
the upper cladding layer comprises a first upper cladding layer, a second upper cladding layer, and a third upper cladding layer, in a sequential arrangement; and the silicon doping concentrations in the first upper cladding layer, the second upper cladding layer and the third upper cladding layer gradually decrease.

17. A method for preparing a photonic crystal electrically pumped surface-emitting laser having a first conductive semiconductor layer, a second conductive semiconductor layer below the first conductive semiconductor layer and a substrate, comprising:
preparing a solution of graphene oxide dilute or MXene;
applying the prepared solution onto the second conductive semiconductor layer having a photonic crystal structure, to obtain a transparent conductive nanomaterial;
stacking transparent conductive materials and metal conductive materials sequentially on the transparent conductive nanomaterial; and
depositing a lower metal electrode beneath the substrate.

18. The method of claim 17, comprising:
preparing the solution of graphene oxide dilute by an improved Hummer's method;
applying the solution of graphene oxide dilute onto the second conductive semiconductor layer and carrying out a Langmuir-Blodgett film self-assembly method to obtain a large-area graphene two-dimensional nanosheet; and
reducing graphene oxide in the large-area graphene two-dimensional nanosheet by hydroiodic acid to obtain the transparent conductive nanomaterial.

19. A method for preparing a photonic crystal electrically pumped surface-emitting laser having a first conductive semiconductor layer, a second conductive semiconductor layer below the first conductive semiconductor layer and a substrate, comprising:
preparing a silver nanowire solution or using a metal-organic vapor deposition method to produce large-area transparent conductive two-dimensional graphene oxide nanosheets on a nickel substrate;
applying the silver nanowire solution or graphene oxide nanosheet onto a second conductive semiconductor layer having a photonic crystal structure, to obtain a transparent conductive nanomaterial;
stacking transparent conductive materials and metal conductive materials on the transparent conductive nanomaterial sequentially; and
depositing a lower metal electrode beneath the substrate.
